(19) United States
(12) Patent Application Publication
(10) Pub. No.: US 2022/0359253 A1
(43) Pub. Date: Nov. 10, 2022

(54) ELECTRONIC COMPONENT TRANSFERRING APPARATUS, ELECTRONIC COMPONENT TRANSFERRING METHOD AND MANUFACTURING METHOD OF LIGHT-EMITTING DIODE PANEL

(71) Applicant: ASTI GLOBAL INC., TAIWAN, Taichung City (TW)

(72) Inventors: Ming-Feng Tu, Taichung City (TW); Chun-Yi Lin, Taichung City (TW); Sheng Che Huang, Taichung City (TW); Chingju Lin, Taichung City (TW)

(73) Assignee: ASTI GLOBAL INC., TAIWAN, Taichung City (TW)

(21) Appl. No.: 17/696,827

(22) Filed: Mar. 16, 2022

Related U.S. Application Data
(60) Provisional application No. 63/185,318, filed on May 6, 2021.
(60) Provisional application No. 63/185,328, filed on May 6, 2021.

(30) Foreign Application Priority Data
Oct. 8, 2021 (TW) 110137455

(51) Int. Cl. H01L 21/68; H01L 33/00; H01L 25/075

(52) U.S. Cl. CPC H01L 21/681; H01L 33/005; H01L 25/0753; H01L 2933/0066

(57) ABSTRACT

An electronic component transferring apparatus is configured to transfer an electronic component on a flexible carrier onto a target substrate. The electronic component transferring apparatus includes a first frame configured to carry the flexible carrier, a second frame configured to carry the target substrate, an abutting component arranged adjacent to the flexible carrier, an actuating mechanism, an energy generating device, and an optical sensing module. The actuating mechanism is configured to actuate the abutting component and move the abutting component in a direction of the flexible carrier, such that an abutting end of the abutting component abuts against the flexible carrier. The energy generating device is configured to generate an energy beam penetrating at least a portion of the abutting component and being directed towards the flexible carrier from the abutting end of the abutting component. The optical sensing module is configured to perform sensing through the abutting component.

### CROSS-REFERENCE TO RELATED APPLICATION

This application claims the priority benefit of U.S. provisional application No. 63/185,318, filed on May 6, 2021, U.S. provisional application No. 63/185,328, filed on May 6, 2021, and Taiwan application no. 110137455, filed on Oct. 8, 2021. The entirety of each of the above-mentioned patent applications is hereby incorporated by reference herein and made a part of this specification.

### BACKGROUND

### Technical Field

The disclosure relates to an electronic component transferring apparatus, an electronic component transferring method, and a manufacturing method of a light-emitting diode panel.

### Description of Related Art

In the manufacturing process of electronic products, related steps of transferring electronic components are required most of the time. For instance, in the manufacturing process of a light-emitting diode display (LED display) panel, the light emitting diodes are often placed on the thin film transistor array substrate (TFT array substrate) by a pick-and-place apparatus first, and then light-emitting diodes located on the TFT array substrate are fixed and electrically connected to the TFT array substrate. However, in the foregoing approach, after the light-emitting diodes are placed on the TFT array substrate and before the light-emitting diodes are fixed to the TFT array substrate, if the environment or equipment is slightly shaken, the unfixed light-emitting diodes may be displaced. Further, the throughput provided by the above approach may be low.

### SUMMARY

The disclosure provides an electronic component transferring apparatus and an electronic component transferring method configured to be used for transferring an electronic component.

The disclosure provides an electronic component transferring apparatus configured to transfer an electronic component on a flexible carrier onto a target substrate. The electronic component transferring apparatus includes a first frame, a second frame, an abutting component, an actuating mechanism, an energy generating device, and an optical sensing module. The first frame is configured to carry the flexible carrier. The second frame is configured to carry the target substrate to allow the target substrate and the flexible carrier to be arranged opposite to each other. The abutting component is arranged adjacent to the flexible carrier, is transparent to light, and has an abutting end. The actuating mechanism is configured to actuate the abutting component and move the abutting component in a direction of the flexible carrier, such that the abutting end of the abutting component abuts against the flexible carrier. The energy generating device is configured to generate an energy beam. The energy beam penetrates at least a portion of the abutting component and is directed towards the flexible carrier from the abutting end of the abutting component. The optical sensing module is configured to perform sensing through the abutting component.

The disclosure further provides an electronic component transferring method, and the method includes the following steps. A flexible carrier is provided. A surface of the flexible carrier carries an electronic component. A target substrate is provided. A surface of the target substrate is provided with a solder pad. The surface of the flexible carrier carrying the electronic component and the surface of the target substrate provided with the solder pad are arranged to be opposite to each other. A solder is provided on at least one of the electronic component and the solder pad. An abutting component transparent to light and located at an original position is provided, the abutting component is moved away from the original position towards a surface of the flexible carrier not carrying the electronic component, the abutting component is allowed to abut against the surface such that the flexible carrier deforms, and the electronic component is allowed to move towards the target substrate. A sensing beam is provided, and the sensing beam is allowed to penetrate the abutting component to reach the flexible carrier and the electronic component to generate a first reflected light signal. An energy beam is provided, the energy beam is allowed to penetrate the abutting component, the solder between the electronic component and the solder pad is melted, and the electronic component is soldered onto the target substrate through the solder. The abutting component returns to the original position, and the sensing beam generates a second reflected light signal. The first reflected light signal and the second reflected light signal are compared to confirm whether the electronic component is transferred onto the target substrate.

The disclosure further provides an electronic component transferring method, and the method includes the following steps. A flexible carrier is provided. A surface of the flexible carrier carries an electronic component. A target substrate is provided. A surface of the target substrate is provided with a solder pad. The surface of the flexible carrier carrying the electronic component and the surface of the target substrate provided with the solder pad are arranged to be opposite to each other. A solder is provided on at least one of the electronic component and the solder pad. An abutting component transparent to light and located at an original position is provided, the abutting component is moved away from the original position towards a surface of the flexible carrier not carrying the electronic component, the abutting component is allowed to abut against the surface such that the flexible carrier deforms, and the electronic component is allowed to move towards the target substrate. The abutting component captures an image of the electronic component to obtain a first image. An energy beam is provided, the energy beam is allowed to penetrate the abutting component, the solder between the electronic component and the solder pad is melted, and the electronic component is soldered onto the target substrate through the solder. The abutting component returns to the original position, and the abutting component captures an image of the electronic component to obtain a second image. The first image and the second image are compared to confirm whether the electronic component is transferred onto the target substrate.

The disclosure further provides a manufacturing method of a light-emitting diode panel, and the method includes the following step. A light-emitting diode chip is transferred to the target substrate through the electronic component transferring method.

To sum up, through the electronic component transferring apparatus and the electronic component transferring method provided by the disclosure, the electronic component on the flexible carrier may be transferred to the target substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1G are partial schematic side views of part of an operation mode of an electronic component transferring apparatus according to a first embodiment of the disclosure.

FIG. 1H and FIG. 1I are schematic diagrams of partial sensing signal sequences of an optical sensing module of an electronic component transferring apparatus according to an embodiment of the disclosure.

FIG. 1J to FIG. 1L are schematic diagrams of partial sensing images of an optical sensing module of an electronic component transferring apparatus according to an embodiment of the disclosure.

FIG. 2 is a partial schematic side view of part of an operation mode of an electronic component transferring apparatus according to a second embodiment of the disclosure.

FIG. 3 is a partial schematic side view of part of an operation mode of an electronic component transferring apparatus according to a third embodiment of the disclosure.

FIG. 4 is a partial schematic side view of part of an operation mode of an electronic component transferring apparatus according to a fourth embodiment of the disclosure.

FIG. 5 is a partial schematic side view of part of an operation mode of an electronic component transferring apparatus according to a fifth embodiment of the disclosure.

### DESCRIPTION OF THE EMBODIMENTS

The content of the following embodiments is for illustration and not for limitation. Further, the description of well-known devices, methods, and materials may be omitted so as not to obscure the description of the various principles of the disclosure. Directional terms (e.g., up, down, top, and bottom) as used herein refer only to the graphical usage or corresponding idioms in the drawings, and are not intended to imply absolute orientation. Besides, unless the content clearly dictates otherwise, the singular forms “a”, “an”, “the”, or forms that do not specifically refer to a quantity may include one or plural forms, i.e., include “at least one”.

In some of the drawings, for the sake of clarity, some of the illustrated components or film layers may be exaggerated, reduced, or omitted. Similar members are referred to by the same reference numbers and exhibit similar functions, materials, or formation methods, and description thereof is omitted. It will be apparent to a person having ordinary skill in the art to which the disclosure pertains, the disclosure may be practiced in other embodiments that depart from the specific details disclosed herein by way of the content of the embodiments and the corresponding illustrations.

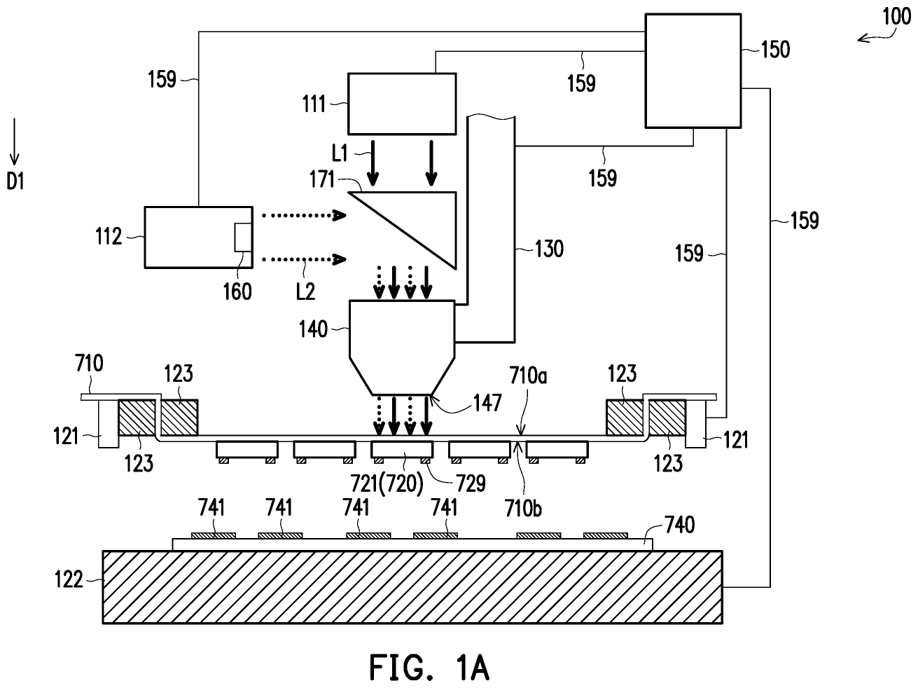

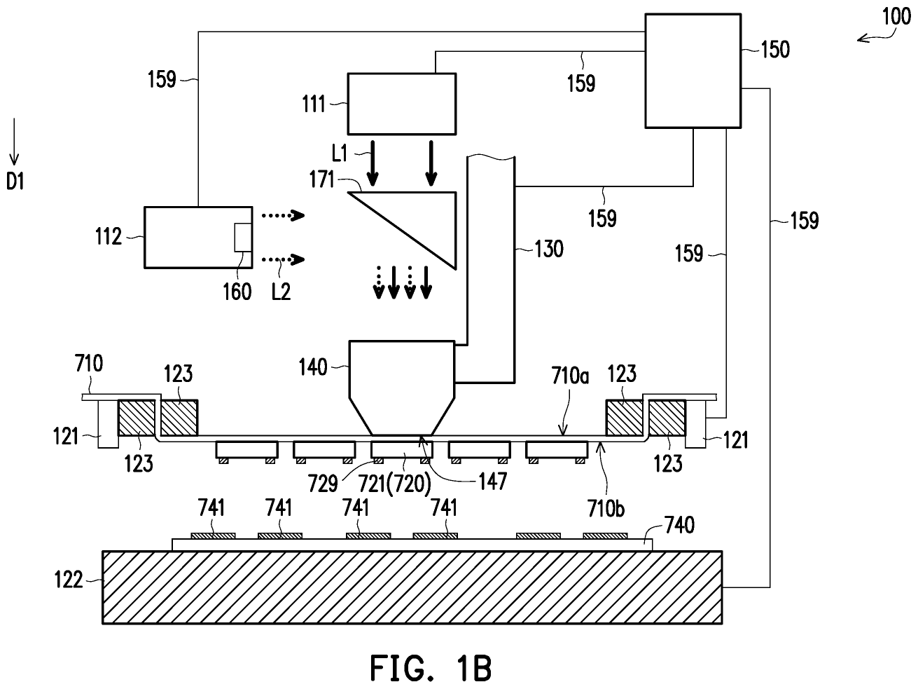

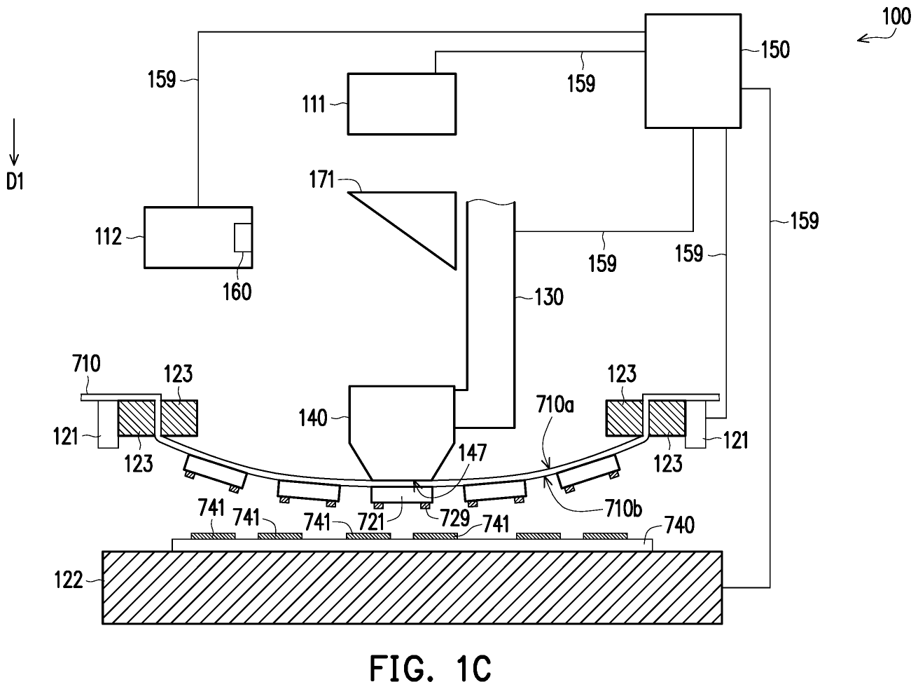

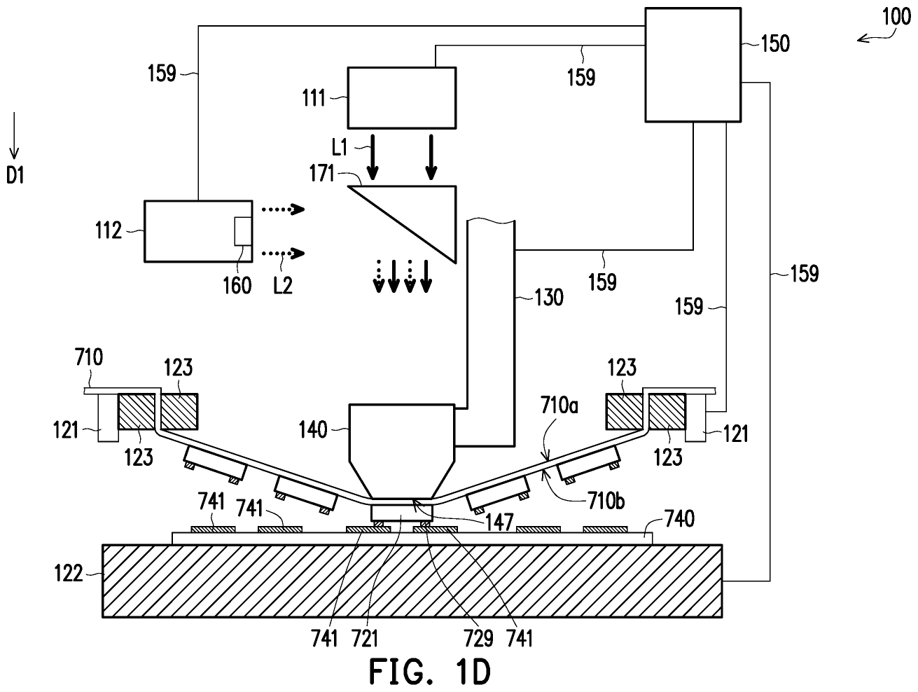

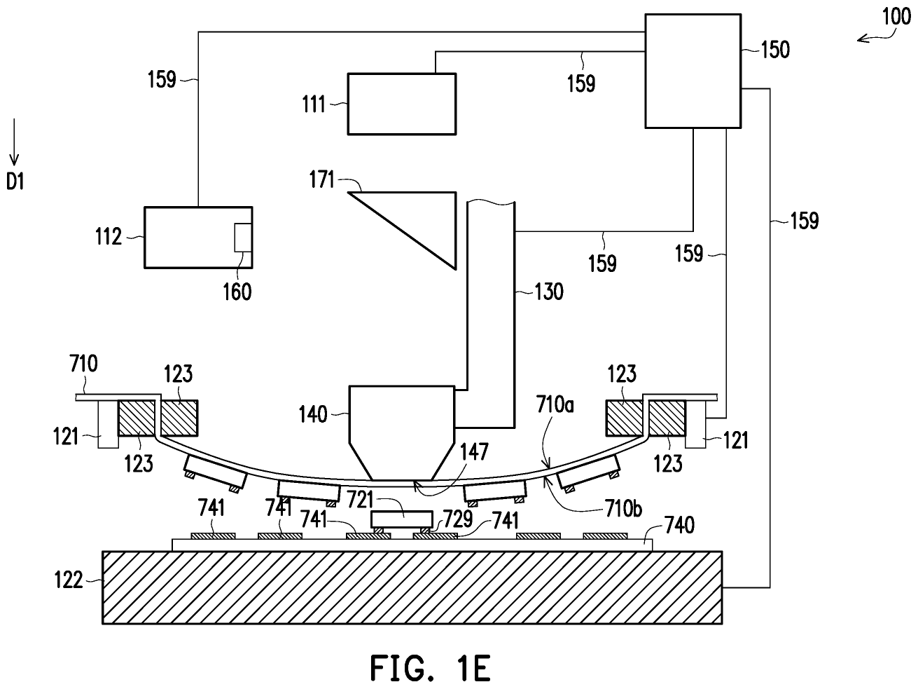

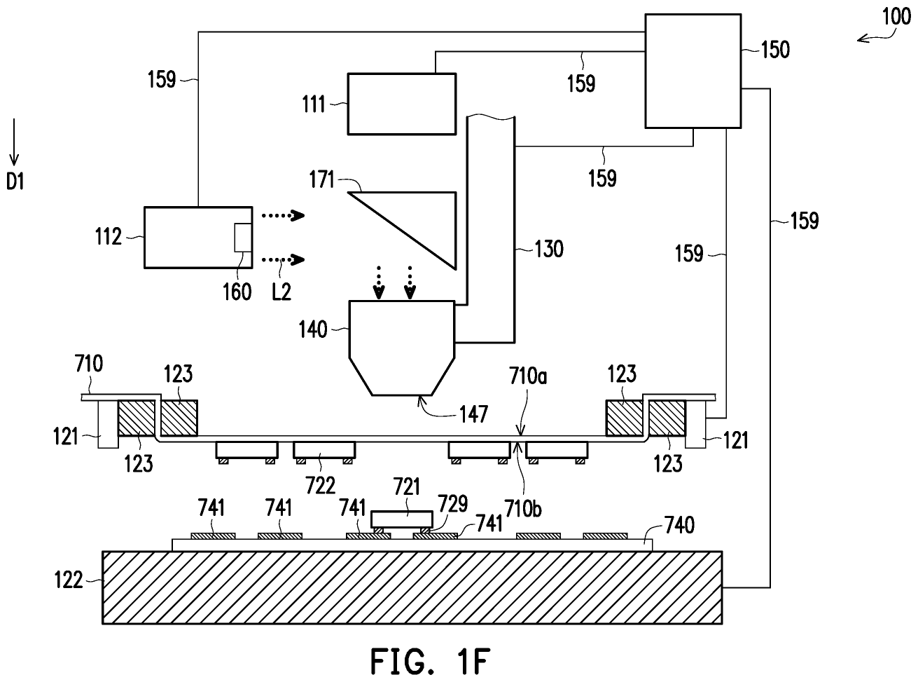

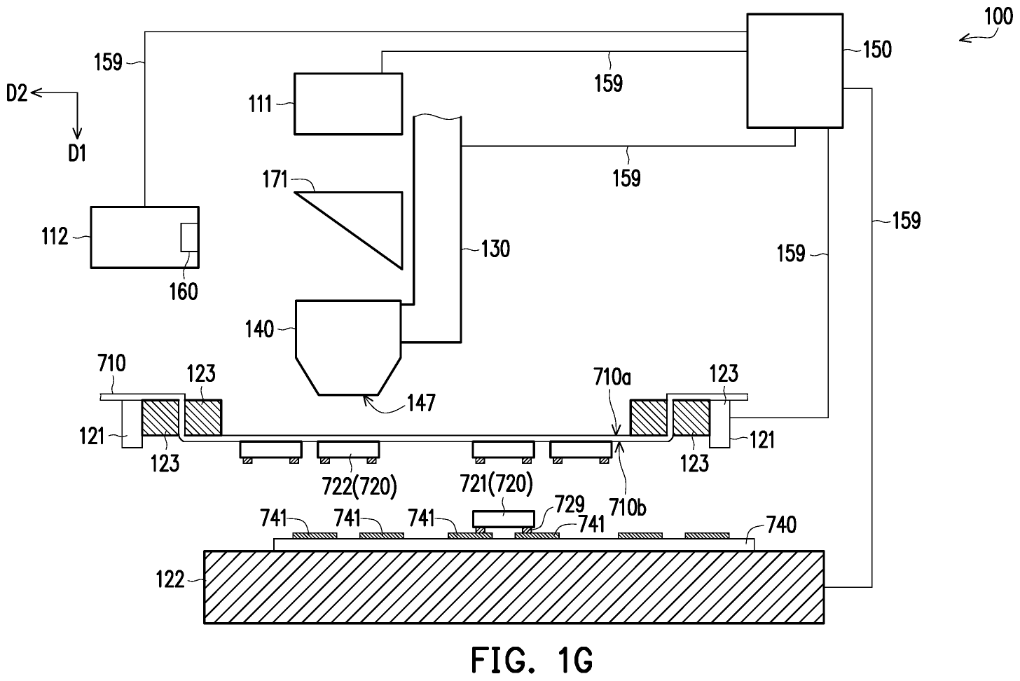

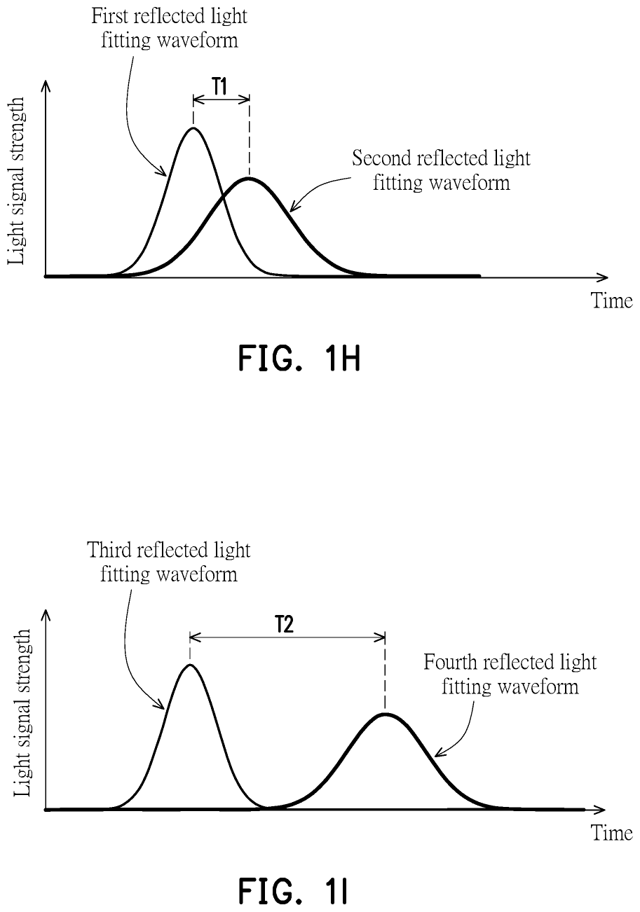

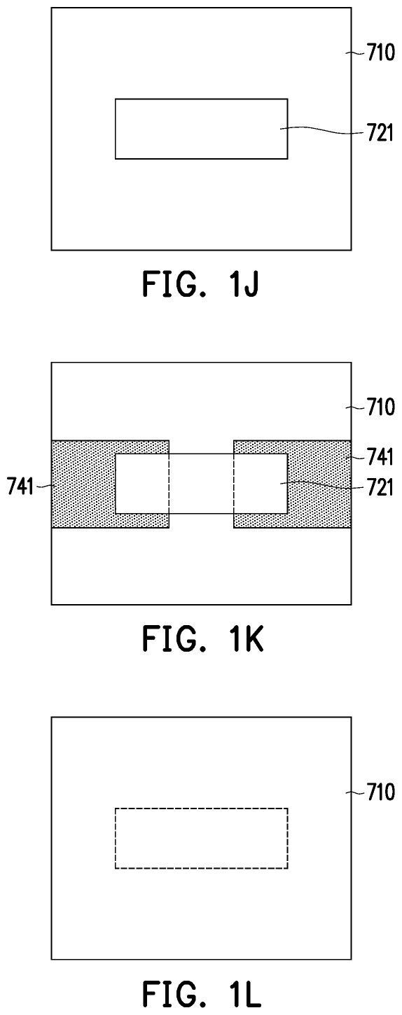

With reference to FIG. 1A, an electronic component transferring apparatus 100 suitable for transferring an electronic component 720 is provided. In this embodiment, the electronic component transferring apparatus 100 can transfer the electronic component 720 from a flexible carrier 710 and allows the electronic component 720 to be soldered to a target substrate 740 (described in detail in the following paragraphs). That is, the electronic component transferring apparatus 100 may be referred to as a transferring and soldering apparatus. The electronic component transferring apparatus 100 includes a first frame 121, a second frame 122, an abutting component 140, an actuating mechanism 130, an energy generating device 111, and an optical sensing module 112. The first frame 121 is configured to carry the flexible carrier 710. The second frame 122 is configured to carry the target substrate 740 to allow the target substrate 740 and the flexible carrier 710 to be arranged opposite to each other. The actuating mechanism 130 is configured to actuate the abutting component 140. A material of the abutting component 140 is transparent to light. The abutting component 140 is arranged adjacent to the flexible carrier 710. When the actuating mechanism 130 actuates the abutting component 140, the abutting component 140 may move in an abutting direction D1 of the flexible carrier 710. Further, an abutting end 147 of the abutting component 140 abuts against the flexible carrier 710, so that the electronic component 720 on the flexible carrier 710 abuts against the target substrate 740.

In this embodiment, the electronic component transferring apparatus 100 may further include a control system 150. The control system 150 may be signal-connected to a corresponding member, component, or unit (such as but not limited to the first frame 121, the second frame 122, the actuating mechanism 130, the energy generating device 111, the optical sensing module 112, and/or an subsequent light receiving component 160) in a form of wired signal transmission through a corresponding signal line 159, but the disclosure is not limited thereto. In an embodiment, the control system 150 may be signal-connected to the corresponding member, component, or unit in a form of wireless signal transmission. That is, the electronic component transferring apparatus 100 including the control system 150 and the first frame 121, the second frame 122, the actuating mechanism 130, the energy generating device 111, and the optical sensing module 112 signal-connected thereto are the same equipment or machine. In addition, the signal connection mentioned in the disclosure can generally refer to the connection mode of wired signal transmission or wireless signal transmission. In addition, the disclosure does not limit all signal connection methods to be the same or different.

In this embodiment, the control system 150 may include corresponding hardware or software.

In an embodiment, the control system 150 includes, for example, an input unit, an output unit, a computing unit, and/or a storage unit. The input unit includes, for example, a keyboard, a mouse, a touch screen, a signal receiving end (e.g., a corresponding data port or an antenna), and/or other similar units suitable for data input. The output unit includes, for example, a screen, a printer, a signal output terminal (e.g., a corresponding data port or an antenna), and/or other similar units suitable for data output. The computing unit includes, for example, a central processing unit (CPU), a graphics processing unit, a physics processing unit (PPU), or other similar units suitable for performing computing, logical determination, signal analysis, and/or data processing. The storage unit includes, for example, memory, hard disk, disk array, database, and/or other similar units suitable for permanent or temporary data storage.

In an embodiment, the control system 150 may also be signal-connected to a could system. The cloud system may perform inputting, outputting, computing, storing, monitoring, data collecting, calculating, and/or other suitable operations through the control system 150 by means of remote control. The cloud system includes, for example, an advanced planning and scheduling system (APS system), a facility monitoring control system (FMCS system), or other suitable industrial control systems (ICS), but the disclosure is not limited thereto.

In an embodiment, the control system 150 includes, for example, software suitable for performing logic determination or a platform and/or a programmable logic controller (PLC) suitable for performing advanced process control (APC), but the disclosure is not limited thereto.

In this embodiment, a material of the first frame 121 may include metal, glass, or plastic, but the disclosure is not limited thereto. In an embodiment, the first frame 121 may include a corresponding fixing member (such as but not limited to a clamp and/or a clip) and may be adapted to fix the flexible carrier 710 directly and/or indirectly. For instance, the first frame 121 may indirectly fix the flexible carrier 710 through a carrier frame 123. For another instance, where the first frame 121 and the flexible carrier 710 contact each other, the flexible carrier 710 may be directly fixed by a frictional force or through other suitable methods.

In an embodiment, the first frame 121 may include a corresponding transmission member (such as but not limited to a roller), and the flexible carrier 710 may be transmitted in an appropriate direction. It should be noted that the aforementioned fixing member and the transmission member may be the same member or different members. For instance, the flexible carrier 710 may be sandwiched between two rollers. When the rollers are not rotated, the flexible carrier 710 may be correspondingly fixed, and when the rollers are rotated, the flexible carrier 710 may be correspondingly transferred.

In an embodiment, the first frame 121 may be fixed or mounted on a movable unit. In this way, the first frame 121 may move and/or rotate in a corresponding direction according to design needs. The movable unit may include a movable module (e.g., a horizontal movement module, a vertical movement module, a rotational movement module, or a combination of the above) commonly used in the design of a movable mechanism, which may include corresponding hardware or software or be further combined with an auxiliary member. For instance, the movable module may have a power supply device, a motor, a belt, a gear, and other related components, which are not limited in the disclosure. The related components include, for example, communication components, power components, etc., which are not limited in the disclosure. The software includes, for example, spatial position calculation software, error recording software, communication software, etc., which is not limited in the disclosure. The auxiliary member includes, for example, a moving rail, a moving shaft, a damping component, a positioning device, etc., which is not limited in the disclosure.

In this embodiment, the flexible carrier 710 may include an ultraviolet tape (UV tape) or a blue tape, but the disclosure is not limited thereto. In an embodiment, the carrier frame 123 may be referred to as a blue film frame, but the disclosure is not limited thereto.

In an embodiment, the flexible carrier 710 may be a composite material. For instance, the flexible carrier 710 may have a polymer film or ultra-thin glass with an adhesive layer covered thereon.

In this embodiment, the actuating mechanism 130 may include a movable module (e.g., a horizontal movement module, a vertical movement module, a rotational movement module, or a combination of the above) commonly used in the design of a movable mechanism, which may include corresponding hardware or software or be further combined with an auxiliary member. For instance, the movable module may have a power supply device, a motor, a belt, a gear, and other related components, which are not limited in the disclosure. The related components include, for example, communication components, power components, etc., which are not limited in the disclosure. The software includes, for example, spatial position calculation software, error recording software, communication software, etc., which is not limited in the disclosure. The auxiliary member includes, for example, a moving rail, a moving shaft, a damping component, a positioning device, etc., which is not limited in the disclosure. In this way, the abutting component 140, which is directly or indirectly fixed to the actuating mechanism 130, may be moved and/or rotated in a corresponding direction according to design needs.

In an embodiment, the abutting component 140 may be indirectly fixed to the actuating mechanism 130, but the disclosure is not limited thereto. For instance, the actuating mechanism 130 may be indirectly fixed to the abutting component 140 via a common fixing member (not shown, such as but not limited to a screw, snap ring, glue and/or corresponding thread between two members) and/or an elastic member (not shown, such as but not limited to an O-ring and/or spring).

In this embodiment, a light source of the electronic component transferring apparatus 100 includes an energy generating device 111 and an optical sensing module 112. The energy generating device 111 is suitable for projecting an energy beam L1, and the optical sensing module 112 is suitable for projecting a sensing beam L2 through a light generating component thereof. At least a portion of a light path of the energy beam L1 is different from at least a portion of a light path of the sensing beam L2. For instance, the energy beam L1 may pass through a prism 171 and be directed towards the abutting component 140, and the sensing beam L2 may reflect off the prism 171 and be directed towards the abutting component 140. Note that for clarity, in FIG. 1A or other similar drawings, a portion of the light path of the energy beam L1 and a portion of the light path of the sensing beam L2 are schematically represented by corresponding arrows. The representation does not limit the energy, wavelengths, optical paths, overall light paths of the energy beam L1 and the sensing beam L2 and/or does not limit whether the energy beam L1 and the sensing beam L2 are projected simultaneously or non-simultaneously. For instance, other suitable optical components (such as but not limited to light reflection components, lenses, filters, apertures, etc.) may be arranged on the corresponding optical paths of the beams.

In an embodiment, the optical sensing module 112 may include an image capturing device, but the disclosure is not limited thereto.

In this embodiment, the material of the abutting component 140 may be suitable for allowing the energy beam L1 and/or the sensing beam L2 to penetrate. The transmittance of the energy beam L1 and/or the sensing beam L2 to the material of the abutting component 140 is, for example, greater than or equal to 50%, greater than or equal to 60%, greater than or equal to 70%, greater than or equal to 75%, greater than or equal to 80%, greater than or equal to 85%, greater than or equal to 90%, greater than or equal to 95%, or greater than or equal to 98%. In an embodiment, the material of the abutting component 140 may be quartz, but the disclosure is not limited thereto. In an embodiment, the material of the abutting component 140 may include sapphire (e.g., synthetic sapphire) or diamond (e.g., synthetic diamond). Note that it is not limited that the transmittance of the energy beam L1 to the material of the abutting component 140 is the same as the transmittance of the sensing beam L2 to the material of the abutting component 140 in the disclosure.

In this embodiment, the abutting component 140 may be a homogeneous material, and the homogeneous material cannot be separated into different single materials by mechanical methods (e.g., crushing, shearing, cutting, sawing, grinding, etc.). In other words, the abutting component 140 may not have interfaces formed by different materials, different processes (e.g., adhesion), and/or different objects (e.g., inserts).

Further, in this embodiment, the energy beam L1 and/or the sensing beam L2 may at least partially penetrate the flexible carrier 710. For instance, the flexible carrier 710 may have a first surface 710a and a second surface 710b, and the second surface 710b is opposite to the first surface 710a. The electronic component 720 is located on the second surface 710b, and the energy beam L1 and/or the sensing beam L2 may at least partially penetrate the flexible carrier 710 in a direction from the first surface 710a to the second surface 710b.

Further, in this embodiment, the optical sensing module 112 may include a corresponding light receiving component 160, and the flexible carrier 710 and the electronic component 720 may reflect a portion of the sensing beam L2. The light receiving component 160 may detect a reflected light signal reflecting off the flexible carrier 710 or the electronic component 720.

In an embodiment, the light receiving component 160 may be arranged on the optical sensing module 112. A light path direction of the reflected light may be substantially parallel and/or substantially opposite to a light path direction of the sensing beam L2 to be sensed by the light receiving component 160. Besides, for the sake of clarity, a light path of the reflected light is not directly shown in FIG. 1A or other similar drawings.

In an embodiment, the energy beam L1 and/or the sensing beam L2 may be laser beams. In an embodiment, the energy beam L1 and/or the sensing beam L2 may be an infrared beam (such as but not limited to a beam with a wavelength of approximately 1,064 nanometers (nm)). For instance, the energy beam L1 may be an infrared laser beam.

In an embodiment, a wavelength of the energy beam is different from a wavelength of the sensing beam. In this way, a signal-to-noise ratio (SNR or S/N) of the light receiving component 160 may be improved. For instance, the energy beam may be an infrared laser beam, and the sensing beam may be a green light range (e.g., a laser beam with a wavelength of approximately 532 nm).

In this embodiment, the second frame 122 may not be transparent to light. A material of the second frame 122 may include metal, plastic, or other materials suitable for supporting or fixing the target substrate 740.

In an embodiment, the second frame 122 may be fixed or mounted on a movable unit (not directly shown). In this way, the second frame 122 may move and/or rotate in a corresponding direction according to design needs.

In this embodiment, the target substrate 740 may include a corresponding circuit, and the circuit may include a corresponding bonding pad 741 exposed to the outside. In an embodiment, the target substrate 740 may include a rigid circuit board or a flexible circuit board, but the disclosure is not limited thereto. In an embodiment, the target substrate 740 may be a circuit board further including an active component (such as but not limited to a thin film transistor array substrate).

In an embodiment, the bonding pad 741 may be adapted to (but not limited to) have a solder arranged thereon. Therefore, the bonding pad 741 may also be referred to as a solder pad.

In this embodiment, the electronic component 720 may include a die and a conductive connecting member 729 arranged on the die, but the disclosure is not limited thereto. The die may include a light-emitting die (such as but not limited to a light-emitting diode die) or an integrated circuit (IC), but the disclosure is not limited thereto. At least one light beam (e.g., one of the energy beam L1) projected by the energy generating device 111 may be adapted to melt at least a portion of the conductive connecting member 729. In an embodiment, the conductive connecting member 729 may include, for example, a solder, but the disclosure is not limited thereto.

In an embodiment that is not shown, the electronic component 720 may include a die similar to the abovementioned die, and the target substrate 740 may have a corresponding conductive connecting member similar to abovementioned conductive connecting member 729.

The manner in which the electronic component 720 is transferred from the flexible carrier 710 to the target substrate 740 by the electronic component transferring apparatus 100 may be as described below. However, it should be noted that the disclosure is not limited to the method described in the following paragraphs.

With reference to FIG. 1A, the electronic component transferring apparatus 100 is provided. Next, the following steps are performed in any order. The target substrate 740 is arranged on the second frame 122 of the electronic component transferring apparatus 100, and the flexible carrier 710 having at least one electronic component 720 arranged thereon is arranged on the first frame 121. Moreover, the electronic component 720 arranged on the flexible carrier 710 is arranged to face the target substrate 740, and a corresponding distance is provided therebetween. It should be noted that in FIG. 1A, the number and/or the arrangement of the electronic component 720 arranged on the flexible carrier 710 are only exemplary, and are not limited in the disclosure. It should be noted that in FIG. 1A, the manner of arranging the target substrate 740 on the second frame 122 of the electronic component transferring apparatus 100 and/or the manner of arranging the flexible carrier 710 on the first frame 121 is only exemplary, and is not limited in the disclosure.

In an embodiment, after the flexible carrier 710 having at least one electronic component 720 arranged thereon and the target substrate 740 are arranged at corresponding positions, the energy generating device 111 may selectively project the energy beam L1 to an electronic component 721 (e.g., one of the electronic component 720), and/or the optical sensing module 112 may selectively project the sensing beam L2 to the electronic component 721.

In an embodiment, the energy beam L1 may include a pre-heated beam, but the disclosure is not limited thereto.

In an embodiment, the sensing beam L2 may be used for alignment or scanning.

In an embodiment, with reference to FIG. 1A and FIG. 1H together, when the electronic component 721 is well arranged on the flexible carrier 710, a portion of the sensing beam L2 may reflect off the flexible carrier 710 and generates a corresponding first reflected light, and another portion of the sensing beam L2 may reflect off the electronic component 721 on the flexible carrier 710 and generates a corresponding second reflected light. Therefore, as shown in FIG. 1H, a first time difference T1 between the first reflected light and the second reflected light may be analyzed by a suitable analytical method (e.g., function fitting). Further, an optical path difference corresponding to the first time difference T1 may be substantially the same as or similar to a thickness of the flexible carrier 710. In this way, it can be determined whether the electronic component 721 is well arranged on the flexible carrier 710. Note that light signal strength of a first reflected light fitting waveform and light signal strength of a second reflected light fitting waveform shown in FIG. 1H are only exemplary. Depending on the material of the actually used flexible carrier, electronic component, or other conditions, the light signal strength of the second reflected light fitting waveform may be greater than the light signal strength of the first reflected light fitting waveform, but the disclosure is not limited thereto.

In an embodiment, when the flexible carrier 710 is excessively thin (e.g., a time difference determination method or result is less than a detection limit), the aforementioned first time difference T1 and/or the corresponding optical path difference may be 0 or close to 0.

In an embodiment, with reference to FIG. 1A and FIG. 1J together, the reflected sensing beam L2 may form an image. As shown in FIG. 1J, when the electronic component 721 is well arranged on the flexible carrier 710, in the image (e.g., the same image or an image similar to the image in FIG. 1J) formed by the sensing beam L2, the flexible carrier 710 and the corresponding electronic component 721 may be provided.

Note that the above determination method is only exemplary, and the detection and/or corresponding determination method of the light receiving component 160 is not limited in the disclosure. For instance, when the flexible carrier 710 and the electronic component 721 have different thicknesses, materials, and/or height positions, the first reflected light and the second reflected light may have different optical features (e.g., having corresponding diffraction fringes). In this way, it can be determined whether the electronic component 721 is well arranged on the flexible carrier 710.

With reference to FIG. 1A to FIG. 1B, the abutting component 140 of the electronic component transferring apparatus 100 and the flexible carrier 710 are brought close to each other in the abutting direction D1, so that the abutting end 147 of the abutting component 140 abuts against a surface (e.g., the first surface 710a) of the flexible carrier 710 that does not carry the electronic component 720.

With reference to FIG. 1B and FIG. 1H/FIG. 1J, when the abutting component 140 abuts against the flexible carrier 710, whether the electronic component 721 is well arranged on the flexible carrier 710 may be selectively determined by the aforementioned method. In an embodiment, whether the electronic component 721 is still located on the flexible carrier 710 may be continuously determined through the aforementioned manner until it is confirmed that the electronic component 721 is well arranged on the target substrate 740.

With reference to FIG. 1B to FIG. 1C, the abutting component 140 may further abut against the flexible carrier 710, so that the flexible carrier 710 is correspondingly deformed (i.e., the flexible carrier 710 is bent towards the direction of the target substrate 740). Further, the electronic component 721 corresponding to the abutting component 140 may be brought close to the target substrate 740 by means of the abutting component 140 being close to the target substrate 740. In this way, as shown in FIG. 1D, the electronic component 721 corresponding to the position where the abutting component 140 abuts against the flexible carrier 710 may be brought into contact with the target substrate 740.

In this embodiment, in a direction parallel to the abutting direction D1, the abutting component 140 may be a moving component, and the first frame 121 and the second frame 122 are not moving components, but the disclosure is not limited thereto. In an embodiment that is not shown, in the direction parallel to the abutting direction D1, the first frame 121 and the second frame 122 may be moving components, and the abutting component 140 is not a moving component. In an embodiment that is not shown, in the direction parallel to the abutting direction D1, the abutting component 140, the first frame 121, and the second frame 122 may all be moving components.

With reference to FIG. 1D, when and/or after the abutting component 140 abuts against the flexible carrier 710 and the abutting component 140 contacts the target substrate 740 at the corresponding electronic element 721, the energy generating device 111 projects the energy beam L1 to the electronic component 721 on the flexible carrier 710. The energy beam L1 may include a heated beam. The heated beam may pass through at least a portion of the abutting component 140 and be emitted from the abutting end 147 of the abutting component 140. In this way, the conductive connecting member 729 of the electronic component 721 corresponding to the abutting component 140 is at least partially melted, and the conductive connecting member 729 which is at least partially melted may contact the corresponding bonding pad 741 on the target substrate 740. Next, the projection of the heated beam may be stopped, and heat may be dissipated by an appropriate method (e.g., by a fan, other active heat dissipation methods, or a passive heat dissipation method such as standing for a period of time), so that the electronic component 721 is soldered on the target substrate 740 to be electrically connected to the corresponding circuit on the target substrate 740.

With reference to FIG. 1D and FIG. 1H, herein, whether the electronic component 721 is well arranged on the flexible carrier 710 may be selectively determined by the aforementioned method.

With reference to FIG. 1D and FIG. 1K, herein, the reflected sensing beam L2 may form an image. As shown in FIG. 1K, when the electronic component 721 is well arranged on the flexible carrier 710 and on the corresponding bonding pad 741, in the image (e.g., the same image or an image similar to the image in FIG. 1K) formed by the sensing beam L2, the electronic component 721 and the corresponding bonding pad 741 may be provided.

With reference to FIG. 1D to FIG. 1E, the abutting component 140 is kept away from the target substrate 740, so that the flexible carrier 710 with appropriate elasticity/deflection may be restored to its original shape as shown in FIG. 1F. Further, since after the electronic component 721 is soldered on the target substrate 740, a bonding force between the electronic component 721 and the target substrate 740 is greater than a bonding force between the electronic component 721 and the flexible carrier 710, the electronic component 721 soldered on the target substrate 740 may be separated from the flexible carrier 710. In this way, the transferring action and the soldering action of the electronic component 721 may be completed through the aforementioned single step.

Through the above exemplary manner, the electronic component 721 may be transferred from the flexible carrier 710 to the target substrate 740 by the electronic component transferring apparatus 100.

In an embodiment, with reference to FIG. 1F and FIG. 1I together, when the electronic component 721 is well transferred onto the target substrate 740, a portion of the sensing beam L2 may reflect off the flexible carrier 710 and generates a corresponding third reflected light, and another portion of the sensing beam L2 may reflect off the electronic component 721 on the flexible carrier 710 and generates a corresponding fourth reflected light. Therefore, as shown in FIG. 1I, a second time difference T2 between the third reflected light and the fourth reflected light may be analyzed by a suitable analytical method (e.g., function fitting). Further, an optical path difference corresponding to the second time difference T2 may be substantially the same or similar to a distance between the electronic component 721 transferred onto the target substrate 740 and the flexible carrier 710. In this way, it can be determined whether the electronic component 721 is well transferred to the target substrate 740. Note that light signal strength of a third reflected light fitting waveform and light signal strength of a fourth reflected light fitting waveform shown in FIG. 1I are only exemplary. Depending on the material of the actually used flexible carrier, electronic component, or other conditions, the light signal strength of the fourth reflected light fitting waveform may be greater than the light signal strength of the third reflected light fitting waveform, but the disclosure is not limited thereto.

In an embodiment, with reference to FIG. 1A and FIG. 1L together, the reflected sensing beam L2 may form an image. As shown in FIG. 1L, when the electronic component 721 is well arranged on the target substrate 740, in the image (e.g., the same image or an image similar to the image in FIG. 1L) formed by the sensing beam L2, the position where the electronic component 721 is originally located (indicated by the dotted line in FIG. 1L) may not have the corresponding electronic component 721. In this way, it can be confirmed whether the electronic component 721 is well transferred to the target substrate 740 through the comparison between the images.

It should be noted that the above determination method is only exemplary. Similar to the aforementioned method, it can be determined whether the electronic component 721 is well transferred to the target substrate 740 by corresponding optical features (e.g., having corresponding diffraction fringes).

With reference to FIG. 1F to FIG. 1G, if the electronic component 721 is well transferred to the target substrate 740, the first frame 121, the second frame 122, the actuating mechanism 130, the energy generating device 111, and/or the optical sensing module 112 may be moved in an appropriate direction (e.g., a direction D2 perpendicular to the abutting direction D1), so as to transfer another electronic component 722 (another one of the electronic component 720) in the same or similar manner as described above.

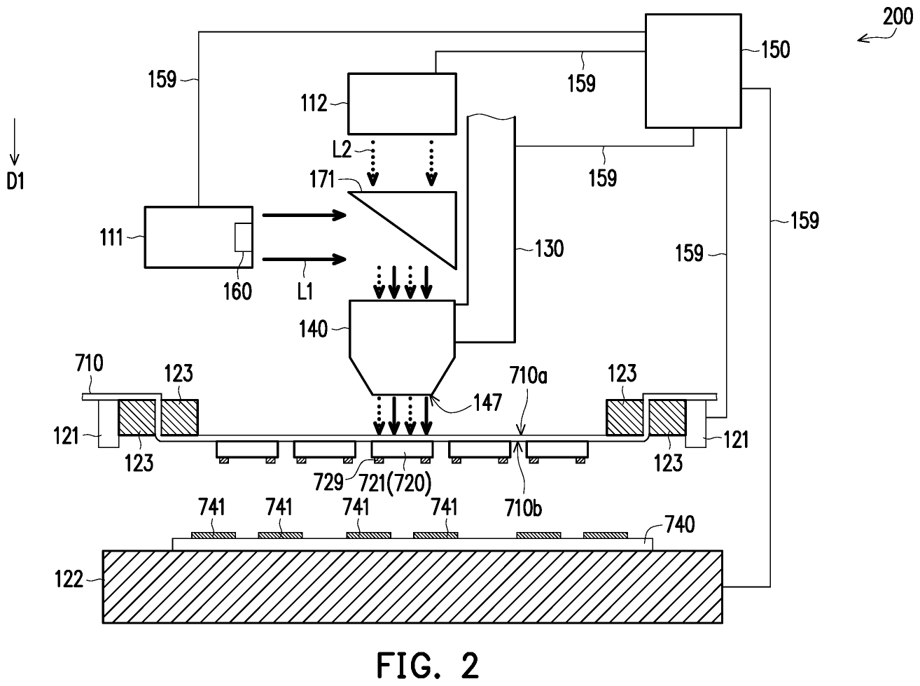

FIG. 2 is a partial schematic side view of part of an operation mode of an electronic component transferring apparatus according to a second embodiment of the disclosure. An electronic component transferring apparatus 200 provided by the embodiment of FIG. 2 is similar to the electronic component transferring apparatus 100 provided by the first embodiment, so similar members are referred to by the same reference numbers and exhibit similar functions, materials, or operation modes, and description thereof is omitted.

With reference to FIG. 2, the electronic component transferring apparatus 200 includes the first frame 121, the second frame 122, the actuating mechanism 130, the energy generating device 111, and the optical sensing module 112. Similar to the above, the electronic component transferring apparatus 200 can transfer the electronic component 720 from the flexible carrier 710 and allows the electronic component 720 to be soldered to the target substrate 740.

In this embodiment, the energy beam L1 may reflect off the prism 171 and be directed towards the abutting component 140, and the sensing beam L2 may pass through the prism and be directed towards the abutting component 140.

In this embodiment, the light receiving component 160 may be arranged on the energy generating device 111. The reflected light (e.g., the aforementioned first reflected light, second reflected light, third reflected light, and fourth reflected light) may be sensed by the light receiving component 160 in a direction parallel to and/or opposite to the light path direction of the energy beam L1.

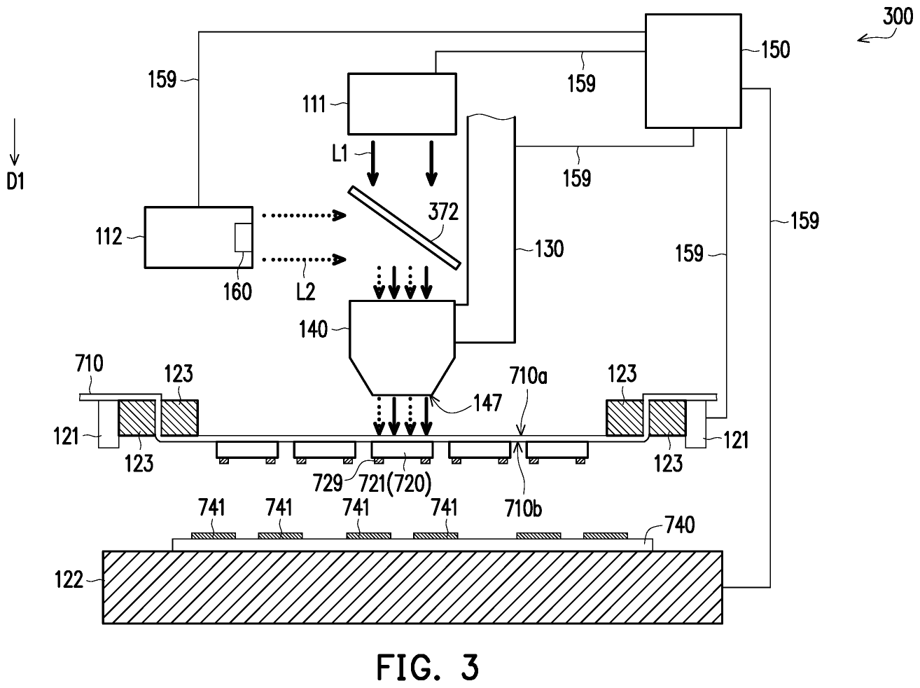

FIG. 3 is a partial schematic side view of part of an operation mode of an electronic component transferring apparatus according to a third embodiment of the disclosure. An electronic component transferring apparatus 300 provided by the embodiment of FIG. 3 is similar to the electronic component transferring apparatus 100 provided by the first embodiment, so similar members are referred to by the same reference numbers and exhibit similar functions, materials, or operation modes, and description thereof is omitted.

With reference to FIG. 3, the electronic component transferring apparatus 300 includes the first frame 121, the second frame 122, the actuating mechanism 130, the energy generating device 111, and the optical sensing module 112. Similar to the above, the electronic component transferring apparatus 300 can transfer the electronic component 720 from the flexible carrier 710 and allows the electronic component 720 to be soldered to the target substrate 740.

In this embodiment, the energy beam L1 may pass through a half reflection half transmission mirror 372 and be directed towards the abutting component 140, and the sensing beam L2 may reflect off the half reflection half transmission mirror 372 and be directed towards the abutting component 140. In an embodiment, the half reflection half transmission mirror 372 is one of beam combiners.

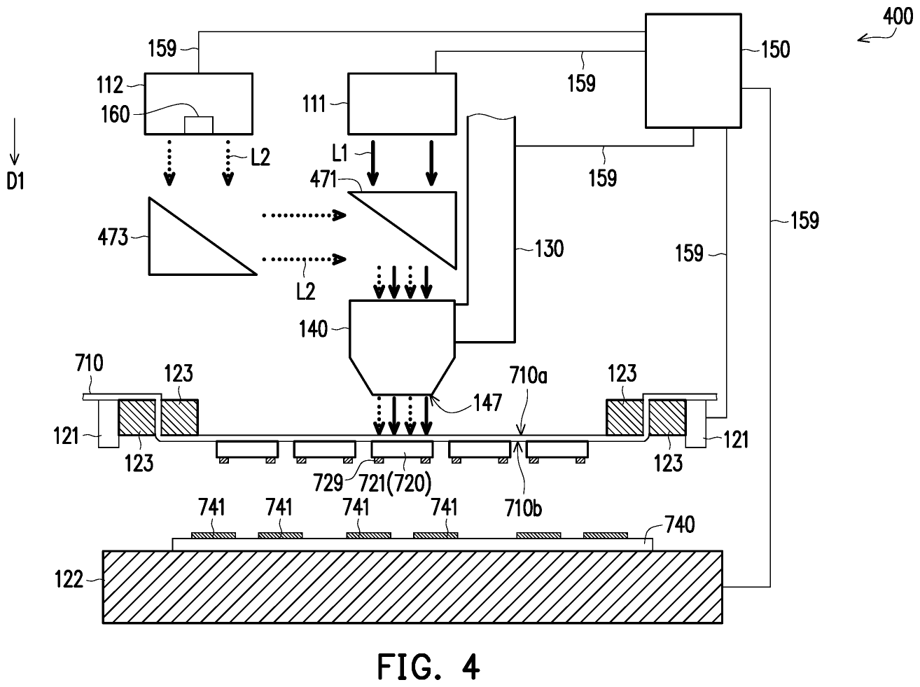

FIG. 4 is a partial schematic side view of part of an operation mode of an electronic component transferring apparatus according to a fourth embodiment of the disclosure. An electronic component transferring apparatus 400 provided by the embodiment of FIG. 4 is similar to the electronic component transferring apparatus 100 provided by the first embodiment, so similar members are referred to by the same reference numbers and exhibit similar functions, materials, or operation modes, and description thereof is omitted.

With reference to FIG. 4, the electronic component transferring apparatus 400 includes the first frame 121, the second frame 122, the actuating mechanism 130, the energy generating device 111, and the optical sensing module 112. Similar to the above, the electronic component transferring apparatus 400 can transfer the electronic component 720 from the flexible carrier 710 and allows the electronic component 720 to be soldered to the target substrate 740.

In this embodiment, the energy beam L1 may pass through prisms and be directed towards the abutting component 140, and the sensing beam L2 may reflect off a prism 471 and a prism 473 and be directed towards the abutting component 140.

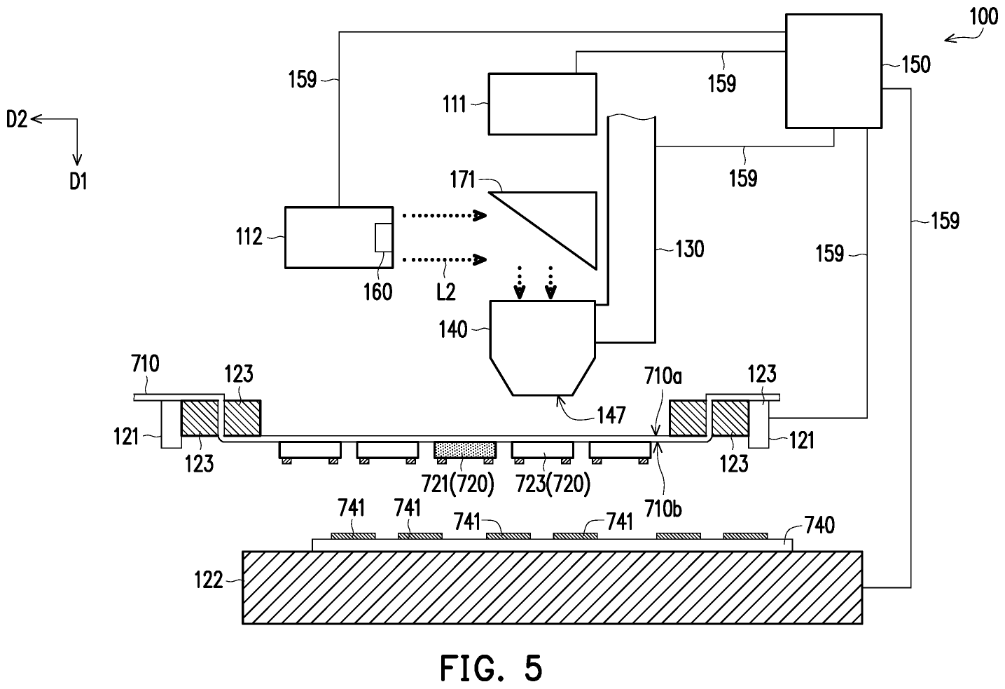

FIG. 5 is a partial schematic side view of part of an operation mode of the electronic component transferring apparatus 100 according to a fifth embodiment of the disclosure. It should be noted that in the operation mode of this embodiment, the electronic component transferring apparatus 100 of the first embodiment is exemplified as an example, but the disclosure is not limited thereto.

With reference to FIG. 1D to FIG. 5, in a possible situation, the electronic component 721 may not be soldered on the target substrate 740, so after the flexible carrier 710 is restored to its original shape, the electronic component 721 may still be located on the flexible carrier 710.

Therefore, the first reflected light generated by the flexible carrier 710 and the second reflected light generated by the electronic component 721 or the corresponding image may not have the picture shown in FIG. 1I or in FIG. 1L.

With reference to FIG. 5, if the electronic component 721 is not well transferred to the target substrate 740, the first frame 121, the second frame 122, the actuating mechanism 130, the energy generating device 111, and/or the optical sensing module 112 may be moved in an appropriate direction (e.g., the direction D2 perpendicular to the abutting direction DO, so that another electronic component 723 (still another one of the electronic component 720) corresponds to the place for transmission, and the another electronic component 723 may be transferred in the same or similar manner as described above.

The electronic component transferring method provided in the foregoing embodiments may be applied to any suitable electronic device. For instance, the electronic component 720 may include a light-emitting diode chip, and the transferring method described above may be part of a manufacturing process of a light-emitting diode panel.

In view of the foregoing, through the electronic component transferring apparatus and the electronic component transferring method provided by the disclosure, the electronic component on the flexible carrier may be transferred to the target substrate.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic component transferring apparatus, configured to transfer an electronic component on a flexible carrier to a target substrate, the electronic component transferring apparatus comprising:
a first frame, configured to carry the flexible carrier;
a second frame, configured to carry the target substrate, wherein the target substrate and the flexible carrier are arranged opposite to each other;
an abutting component, arranged adjacent to the flexible carrier, transparent to light, and having an abutting end;
an actuating mechanism, configured to actuate the abutting component and move the abutting component in a direction of the flexible carrier, such that the abutting end of the abutting component abuts against the flexible carrier;
an energy generating device, configured to generate an energy beam, wherein the energy beam penetrates at least a portion of the abutting component and is directed towards the flexible carrier from the abutting end of the abutting component; and
an optical sensing module, configured to perform sensing through the abutting component.

2. The electronic component transferring apparatus according to claim 1, wherein the energy generating device is a laser generating device, and the energy beam generated by the laser generating device is a laser beam.

3. The electronic component transferring apparatus according to claim 1, wherein the optical sensing module comprises a light generating component and a light receiving component, the light generating component projects a sensing beam, the sensing beam penetrates at least a portion of the abutting component and is directed towards the flexible carrier from the abutting end of the abutting component, and the light receiving component receives a reflected light signal which is generated after the sensing beam is projected.

4. The electronic component transferring apparatus according to claim 1, wherein the optical sensing module is an image capturing device and captures an image through the abutting component.

5. An electronic component transferring method, comprising:
providing a flexible carrier, wherein a surface of the flexible carrier carries an electronic component,
providing a target substrate, wherein a surface of the target substrate is provided with a solder pad;
arranging the surface of the flexible carrier carrying the electronic component and the surface of the target substrate provided with the solder pad to be opposite to each other, wherein a solder is provided on at least one of the electronic component and the solder pad;
providing an abutting component transparent to light and located at an original position, moving the abutting component away from the original position towards a surface of the flexible carrier not carrying the electronic component, allowing the abutting component to abut against the surface such that the flexible carrier deforms, and allowing the electronic component to move towards the target substrate;
providing a sensing beam and allowing the sensing beam to penetrate the abutting component to reach the flexible carrier and the electronic component to generate a first reflected light signal;
providing an energy beam, allowing the energy beam to penetrate the abutting component, melting the solder between the electronic component and the solder pad, and soldering the electronic component onto the target substrate through the solder;
returning the abutting component to the original position and generating, by the sensing beam, a second reflected light signal; and
comparing the first reflected light signal and the second reflected light signal to confirm whether the electronic component is transferred onto the target substrate.

6. The electronic component transferring method according to claim 5, wherein the sensing beam is continuously provided during the period when the abutting component is located at the original position and is returned to the original position.

7. The electronic component transferring method according to claim 5, wherein the sensing beam is provided at any time when the abutting component is located at the original position until the electronic component is allowed to abut against the solder pad on the target substrate and is provided again when the abutting component returns to the original position.

8. An electronic component transferring method, comprising:
providing a flexible carrier, wherein a surface of the flexible carrier carries an electronic component,
providing a target substrate, wherein a surface of the target substrate is provided with a solder pad;
arranging the surface of the flexible carrier carrying the electronic component and the surface of the target substrate provided with the solder pad to be opposite to each other, wherein a solder is provided on at least one of the electronic component and the solder pad;
providing an abutting component transparent to light and located at an original position, moving the abutting component away from the original position towards a surface of the flexible carrier not carrying the electronic component, allowing the abutting component to abut against the surface such that the flexible carrier deforms, and allowing the electronic component to move towards the target substrate;
capturing, by the abutting component, an image of the electronic component to obtain a first image;
providing an energy beam, allowing the energy beam to penetrate the abutting component, melting the solder between the electronic component and the solder pad, and soldering the electronic component on the target substrate through the solder;
returning the abutting component to the original position, capturing, by the abutting component, an image of the electronic component to obtain a second image; and
comparing the first image and the second image to confirm whether the electronic component is transferred onto the target substrate.

9. A manufacturing method of a light-emitting diode panel, comprising the electronic component transferring method according to claim 5 to transfer a light-emitting diode chip onto the target substrate.

10. A manufacturing method of a light-emitting diode panel, comprising the electronic component transferring method according to claim 8 to transfer a light-emitting diode chip onto the target substrate.
